(19) United States
(12) Patent Application Publication
(10) Pub. No.: US 2013/0105907 A1
(43) Pub. Date: May 2, 2013

(54) MOS DEVICE AND METHOD OF MANUFACTURING THE SAME

(71) Applicants: Huaxiang Yin, Beijing (CN); Qiuxia Xu, Beijing (CN); Dapeng Chen, Beijing (CN)

(72) Inventors: Huaxiang Yin, Beijing (CN); Qiuxia Xu, Beijing (CN); Dapeng Chen, Beijing (CN)

(21) Appl. No.: 13/513,198

(22) PCT Filed: Nov. 28, 2011
(86) PCT No.: PCT/CN11/01982

§ 371 Date: Jun. 1, 2012

(30) Foreign Application Priority Data
Oct. 26, 2011 (CN) 201110329077.X

(51) Int. Cl. H01L 27/092; H01L 21/8238

(52) U.S. Cl. 257/369; 438/199; 257/E27.062; 257/E21.632

(57) ABSTRACT

The present invention relates to a MOS device and method of manufacturing the same. The device comprises a semiconductor substrate; a channel formed in the semiconductor substrate; a gate stack formed on the channel and a spacer surrounding the gate stack; and source and drain regions formed in the substrates on both sides of the spacer; wherein the gate stack is comprised of an insulating layer and a multi-layer metal gate formed thereon, the multi-layer metal gate is comprised of a strained metal layer for introducing a stress to the channel and a work function regulating layer for regulating the work function of the metal gate, and the work function regulating layer surrounds the strained metal layer from the bottom and sides. The multi-layer metal gate structure overcomes the defect incurred by the fact that a conventional strained metal gate material can not achieve both regulation of work function and effect of application of strain be optimized at the same time.

### CROSS REFERENCE

This application is a National Phase application of, and claims priority to, PCT Application No.PCT/CN2011/001982, filed on Nov. 28 , 2011, entitled ‘MOS DEVICE AND METHOD OF MANUFACTURING THE SAME’, which claimed priority to Chinese Application No. CN 201110329077.X, filed on Oct. 26, 2011. Both the PCT Application and Chinese Application are incorporated herein by reference in their entireties.

### FIELD OF THE INVENTION

The present invention relates to the semiconductor field, more particularly, to a MOS device and method of manufacturing the same.

### BACKGROUND OF THE INVENTION

Starting from the 90 nm CMOS integrated circuit technology, with continuous reduction in the device feature size, strain channel engineering for the purpose of enhancing the channel carrier mobility plays a more and more important role. Various strain techniques are integrated into the device process to improve the driving capability of a device. One of the methods is to produce “global stress”, which is generally produced by using the structures such as a strained SiGe substrate, a strained silicon substrate grown on a SiGe relaxed buffer layer, or strained silicon on an insulator. Another method is to produce “local stress”, which is generally produced by induction of a uniaxial process by using the structures such as a shallow trench isolation structure that produces stress, (dual) stress liner, a SiGe structure embedded into source and drain (S/D) regions of a PMOS (e-SiGe), and a SiC structure embedded into the source and drain (S/D) regions of an NMOS (e-SiC). However, these conventional stress technical effects will be continuously reduced as the device feature size reduces, rendering that the device driving capability can not be increased to a predetermined target.

The strain metal gate engineering provides a new source for generating stress to the channel, which may overcome the unfavorable influence where the effect of conventional stress sources such as a source/drain heteroepitaxial layer and a strained liner insulating layer is continuously weakened as the device feature size reduces. As shown in FIG. 1, in a MOS device 10, a conventional strained metal gate material 105 (e.g., TiN, TaN) is in direct contact with a gate insulating material 110 (e.g., silicon oxide, high-K dielectrics). The primary goal for such configuration is to regulate the work function of the metal gate, and to take the effect of the intrinsic strain of gate material on the channel below the gate insulating material into account. However, the optimal effect of function of the same material is limited for different functional requirements.

In view of the above reason, there still exists a need for a method for producing strain in the channel of a MOS device and a semiconductor structure. The above limitation may be overcome by the method and device.

### SUMMARY OF THE INVENTION

To achieve the above object, in a first aspect of the invention, there is provided a MOS device, comprising: a semiconductor substrate; a channel formed in the semiconductor substrate; a gate stack formed on the channel and a spacer surrounding the gate stack; and source and drain regions formed in the substrate on both sides of the spacer; wherein the gate stack is comprised of an insulating layer and a multi-layer metal gate formed thereon, the multi-layer metal gate is comprised of a strained metal layer for introducing a stress to the channel and a work function regulating layer for regulating the work function of the metal gate, and the work function regulating layer surrounds the strained metal layer from the bottom and sides.

In a second aspect of the present invention, there is provided a method for manufacturing a MOS device, comprising the steps of: providing an initial structure including a semiconductor substrate, a channel formed in the semiconductor substrate; a gate stack including a gate insulating layer and a sacrificial gate formed on the gate insulating layer above the channel; a spacer surrounding the gate stack, and source and drain regions formed in the substrate on both sides of the spacer; removing the sacrificial gate; forming a work function regulating layer for regulating the work function of a multi-layer metal gate to be formed in a opening which is formed after removing the sacrificial gate; and forming a strained metal layer for introducing a stress to the channel, the work function regulating layer surrounding the strained metal layer from the bottom and sides, and the strained metal layer and the work function regulating layer forming the multi-layer metal gate.

In a third aspect of the invention, there is provided a MOS device, comprising: a semiconductor substrate; a channel formed in the semiconductor substrate; a gate stack formed on the channel and a spacer surrounding the gate stack; and source and drain regions formed in the substrate on both sides of the spacer; wherein the gate stack is comprised of a gate insulating layer and a multi-layer metal gate formed thereon, the multi-layer metal gate is comprised of a work function regulating layer for regulating the work function of the metal gate and a strained metal layer formed on its top for introducing a stress to the channel.

In a fourth aspect of the present invention, there is provided a method for manufacturing a MOS device, comprising the steps of: providing a semiconductor substrate; forming a channel in the semiconductor substrate; forming sequentially on the semiconductor substrate a gate insulating layer, a work function regulating layer for regulating the work function and a strained metal layer for introducing a stress to the channel; patterning a part of the gate insulating layer, work function regulating layer and strained metal layer to form a gate stack layer, wherein the gate stack layer is comprised of the remaining gate insulating layer, work function regulating layer and strained metal layer; forming a spacer on both sides of the gate stack layer; and forming source and drain regions in the substrate on both sides of the spacer.

In the multi-layer metal gate structure, the work function regulating layer optimizes the corresponding work function (that is, more close to the top of the valence band or the bottom of the conduction band) by optimizing the material, component, fabrication process and processing method, thereby to regulate the device threshold to be optimal; the strained metal layer optimizes the corresponding intrinsic stress of the material (that is, compressive stress and tensile stress) by optimizing the material, component, fabrication process and processing method, thereby to apply a more effective strain effect to the channel of the device. Such a structure overcomes the defect incurred by the fact that a conventional strained metal gate can not achieve both regulation of work function and effect of application of strain be optimized at the same time.

### BRIEF DESCRIPTION OF THE DRAWINGS

The embodiments may be best understood by making reference to the descriptions below and the drawings for illustrating the embodiments, wherein:

FIG. 1 is a cross-sectional view of a MOS device having a conventional strained metal gate;

FIGS. 2-6 are cross-sectional views showing the device structure corresponding to the steps in the first embodiment; and

FIGS. 7-12 are cross-sectional views showing the device structure corresponding to the steps in the second embodiment.

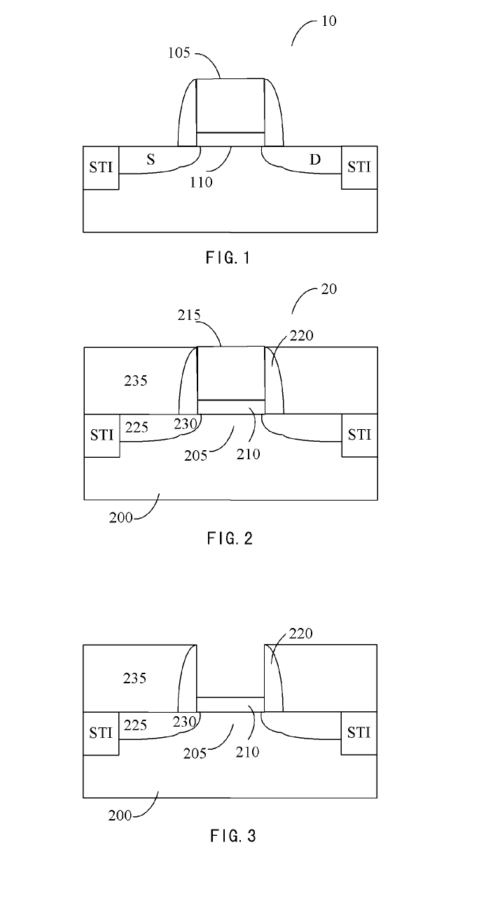

### DETAILED DESCRIPTION OF THE EMBODIMENTS

One or more aspects of the embodiment of the present invention will described with reference to the accompanying drawings below, where like elements will be generally indicated by like reference signs throughout the drawings. In the following descriptions, many specific details are elaborated for the purpose of explanation so as to facilitate thorough understanding of one or more aspects of the embodiment of the present invention. However, it may be apparent to a person skilled in the art that they may use few of these specific details to implement one or more aspects of the embodiment of the present invention.

### Embodiment 1

This embodiment is directed to a MOS device manufactured by a gate-last process. An initial structure 20 as shown in FIG. 2 is provided as a start. The initial structure 20 comprises a semiconductor substrate 200, a channel 205 formed in the semiconductor substrate, a gate stack (including a gate insulating layer 210 and a sacrificial gate 215) formed above the channel 205, a spacer 220 surrounding the gate stack, source and drain regions 225 formed in the substrate on both sides of the spacer and source and drain extension areas 230 formed below the spacer, metal contact regions (including silicide contacts (not shown)) formed on the source and drain regions 225 later and an interlayer dielectric layer 235 for isolating the devices. Furthermore, each two of the MOS devices may also be separated from each other by an isolation region, which may be, for example, a shallow trench isolation (STI) or field isolation region and may be formed of stressed materials or unstressed materials.

The materials for forming the gate insulating layer 210 may be, for example, various dielectric materials or the composite multi-layer structures thereof. The dielectric materials may include but not limited to HfO₂, HfSiOₓ, HfSiON, HfAlOₓ, HfTaOₓ, HfLaOₓ, HfAlSiOₓ, and HfLaSiOₓ, etc., rare-earth based high K dielectric materials such as ZrO₂, La₂O₃, LaAlO₃, TiO₂, Y₂O₃ etc., and SiO₂, SiON, Si₃N₄, Al₂O₃ etc. The gate insulating layer may be formed by a deposition process such as chemical vapor deposition (CVD), plasma assisted CVD, atomic layer deposition (ALD), evaporation, reaction sputtering, chemical solution deposition and other similar deposition processes or the combination of any of the above processes.

The sacrificial gate 215 may be formed of, e.g., polysilicon or other materials commonly known in the art.

Optionally, a conventional stressed structure (not shown in the drawings) may be embedded into the source and drain regions on both sides of the gate stack. As for the NMOS device, for example, an SiC (e-SiC) structure or a structure that can provide a tensile stress to the channel formed by any future techniques is embedded into the source and drain regions. As for the PMOS device, for example, an SiGe (e-SiGe) structure or a structure that can provide a compressive stress to the channel formed by any future techniques is embedded into the source and drain regions.

Optionally, a stress liner (not shown) may also be formed on the top of the structure of the device already formed prior to the formation of the interlayer dielectric layer 235 and may be planarized with the interlayer dielectric layer 235 upon the formation of the interlayer dielectric layer 235 to expose the surface of the sacrificial gate 215. Depending on the type of the MOS device, the liner may apply a corresponding stress to the channel region under the gate stack. The stress liner may either be a nitride liner or an oxide liner. However, it may be appreciated by a person skilled in the art that the stress liner is not limited to the nitride liner or the oxide liner, other stress liner materials may also be used. The method for forming the stress liner may include but not limit to the plasma enhanced chemical vapor deposition (PECVD) process.

Then, the sacrificial gate 215 is removed, as shown in FIG. 3. The gate insulating layer 210 under the sacrificial gate may remain intact or substantially intact. In a preferred embodiment, since the above removing process may cause damage to the gate insulating layer 210 below, preferably, the gate insulating layer 210 is removed together with the sacrificial gate 215 and then a new gate insulating layer 210 is remanufactured. The materials for the new gate insulating layer may be, for example, various dielectric materials or the composite multi-layer structures thereof. The dielectric materials may include but not limited to HfO₂, HfSiOₓ, HfSiON, HfAlOₓ, HfTaOₓ, HfLaOₓ, HfAlSiOₓ, and HfLaSiOₓ etc., rare-earth based high K dielectric materials such as ZrO₂, La₂O₃, LaAlO₃, TiO₂, Y₂O₃ etc., and SiO₂, SiON, Si₃N₄, Al₂O₃ etc.

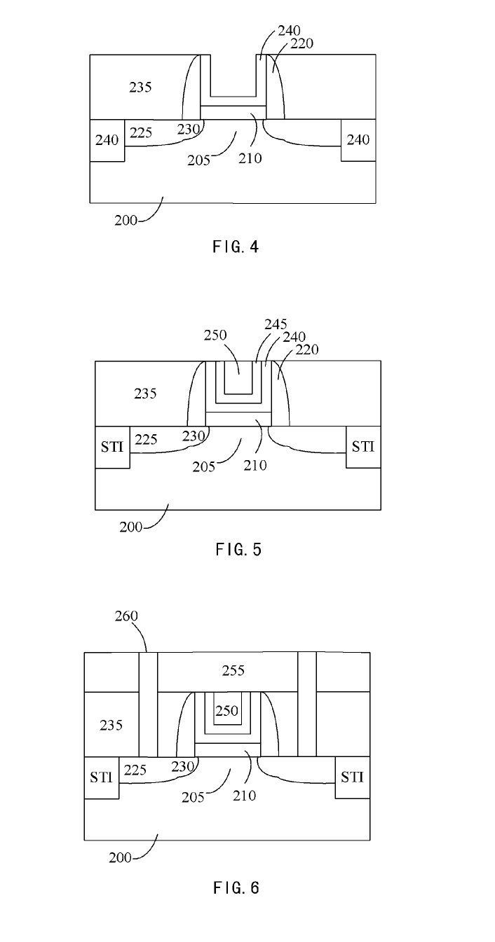

Next, a work function regulating layer 240 is formed in an opening which is formed after removing the sacrificial gate. The work function regulating layer 240 is formed on the sidewall and bottom of the opening, as shown in FIG. 4. The work function regulating layer is used for regulating the work function of a metal gate. The materials for the work function regulating layer may be selected from the groups as follows: (1) Mₓ₁N_{y1}, Mₓ₂Si_{y2}N_{z1}, Mₓ₃Al_{y3}N_{z2} or MₐAlₓ₃Si_{y3}N_{z2} deposited by chemical vapor deposition (CVD), plasma assisted CVD (PECVD), atomic layer deposition (ALD), sputtering or other similar deposition processes; (2) a compound of the formula Mₓ₁N_{y1}, Mₓ₂Si_{y2}N_{z1}, Mₓ₃Al_{y3}N_{z2} or MₐAlₓ₃Si_{y3}N_{z2} and metal Co, Ni, Cu, Al, Pd, Pt, Ru, Re, Mo, Ta, Ti, Hf, Zr, W, Ir, Eu, Nd, Er or La sequentially deposited by the above processes, that is, a composite layer comprised of the compound and the metal; or (3) Mₓ₁N_{y1}, Mₓ₂Si_{y2}N_{z1}, Mₓ₃Al_{y3}N_{z2} or MₐAlₓ₃Si_{y3}N_{z2} deposited by the above processes, in which metal Co, Ni, Cu, Al, Pd, Pt, Ru, Re, Mo, Ta, Ti, Hf, Zr, W, Ir, Eu, Nd, Er or La is doped. Wherein letter “M” represents Ta, Ti, Hf, Zr, Mo or W; and a, x1-x3, y1-y3 and z1-z2 are the number of atoms of the element in the compound. So long as M is specific, a, x1-x3, y1-y3 and z1-z2 are also determined. Here, it shall be noted that as for an NMOS, an appropriate element M and an appropriate metal element to be doped shall be selected, and the numerical value for a, x1-x3, y1-y3 and z1-z2 as well as the deposition process shall be regulated such that the work function of the material can approach the bottom of the conduction band; as for a PMOS, an appropriate element M and an appropriate metal element to be doped shall be selected, and the numerical value for a, x1-x3, y1-y3 and z1-z2 as well as the deposition process shall be regulated such that the work function of the material can approach the top of the valence band. As for how to select corresponding process parameters and materials for the NMOS or the PMOS such that the work function of the material can approach the bottom of the conduction band or the top of the valence band, it is well known by a person skilled in the art, no more unnecessary details will be provided here.

Thereafter, a strained metal layer 250 is formed on the sidewall and bottom of the work function regulating layer 240, that is, the work function regulating layer 240 surrounds the strained metal layer 250 from the bottom and sides, as shown in FIG. 5. The strained metal layer introduces a stress to the channel. The materials for the strained metal layer 250 may be selected from the groups as follows: (1) high-stress (the tensile stress>3 Gpa or the compressive stress<−3 Gpa) Mₓ₁N_{y1}, Mₓ₂Si_{y2}N_{z1}, Mₓ₃Al_{y3}N_{z2} or MₐAlₓ₃Si_{y3}N_{z2} deposited by CVD, PECVD, ALD or sputtering; (2) high-stress (the tensile stress>3 Gpa or the compressive stress<−3 Gpa) pure metal Co, Ni, Cu, Al, Pd, Pt, Ru, Re, Mo, Ta, Ti, Hf, Zr, W, Ir, Eu, Nd, Er or La deposited by the above similar processes; (3) high-stress (the tensile stress>3 Gpa or the compressive stress<−3 Gpa) Mₓ₁N_{y1}, Mₓ₂Si_{y2}N_{z1}, Mₓ₃Al_{y3}N_{z2} or MₐAlₓ₃Si_{y3}N_{z2}deposited by the above similar processes, in which metal Co, Ni, Cu, Al, Pd, Pt, Ru, Re, Mo, Ta, Ti, Hf, Zr, W, Ir, Eu, Nd, Er or La is doped; (4) metalization reactants of Si or Ge such as CoSi₂, TiSi₂, NiSi, PtSi, NiPtSi, CoGeSi, TiGeSi or NiGeSi; (5) high-stress (the tensile stress>3 Gpa or the compressive stress<−3 Gpa) metal oxide deposited by the above similar processes such as In₂O₃, SnO₂, ITO, or IZO; (6) high-stress (the tensile stress>3 Gpa or the compressive stress<−3 Gpa) polysilicon, amorphous silicon, polycrystalline germanium, or polycrystalline silicon-germanium deposited by the above similar processes; or (7) any one of the materials in the above (1)-(6) which has experienced the high temperature rapid thermal annealing process (for example, laser annealing or spike annealing), in which C,F,N,O,B,P or As may also be ion implanted. Wherein letter “M” represents Ta, Ti, Hf, Zr, Mo or W; and a, x1-x3, y1-y3 and z1-z2 are the number of atoms of the element in the compound. So long as M is specific, a, x1-x3, y1-y3 and z1-z2 are also determined. Here, it shall be noted that as for an NMOS, an appropriate metal material and ratio of components, an appropriate deposition process and post-processing method shall be selected such that the intrinsic stress of the material is a compressive stress and is greater than 3 Gpa; as for a PMOS, an appropriate metal material and ratio of components, an appropriate deposition process and post-processing method shall be selected such that the intrinsic stress of the material is a tensile stress and is greater than 3 Gpa. As for how to select corresponding process parameters and materials for the NMOS or the PMOS such that its intrinsic stress is greater than 3 Gpa, it may be achieved by a person skilled in the art through limited experiments, no more unnecessary details will be provided here.

Preferably, a blocking layer 245 may also be formed between the work function regulating layer 240 and the strained metal layer 250, as shown in FIG. 5. The blocking layer may suppress the mutual diffusion of different elements in the work function regulating layer and the strained metal layer, thereby improving the stability of the work function of the metal material at the surface, and improving the adhesivity of the strained metal layer and the gate structure in the mean time. The materials for the blocking layer may be selected from the group as follows: Mₓ₁N_{y1}, Mₓ₂Si_{y2}N_{z1}, Mₓ₃Al_{y3}N_{z2} or MₐAlₓ₃Si_{y3}N_{z2} deposited by CVD, PECVD, ALD or sputtering. Wherein letter “M” represents Ta, Ti, Hf, Zr, Mo or W; and a, x1-x3, y1-y3 and z1-z2 are the number of atoms of the element in the compound. So long as M is specific, a, x1-x3, y1-y3 and z1-z2 are also determined.

The above work function regulating layer 240, strained metal layer 250, and blocking layer 245 (if any) form a multi-layer metal gate structure. The multi-layer metal gate and the gate insulating layer form a new gate stack. The work function regulating layer 240 in the multi-layer structure optimizes the corresponding work function (that is, more close to the top of the valence band or the bottom of the conduction band) by optimizing the material, component, process and processing method, thereby to regulate the device threshold to be optimal; the strained metal layer 250 optimizes the corresponding intrinsic stress of the material (that is, compressive stress and tensile stress) by optimizing the material, component, process and processing method, thereby to apply a more effective strain effect to the channel of the device; the blocking layer 245 improves the stability and the material compatibility. Such a structure overcomes the defect incurred by the fact that a conventional strained metal gate material 105 can not achieve both regulation of work function and effect of application of strain be optimized at the same time.

Next, through other well-known steps, such as forming another interlayer dielectric layer 225 on the top surface of the sources and drain regions as well as the gate stack for contact, and forming metal contacts 260, thus the MOS device as shown in FIG. 6 is formed. In any of the cases, in order not to blur the essence of the present invention, a person skilled in the art may get to know the details of these steps by referring to other publications or patents.

### Embodiment 2

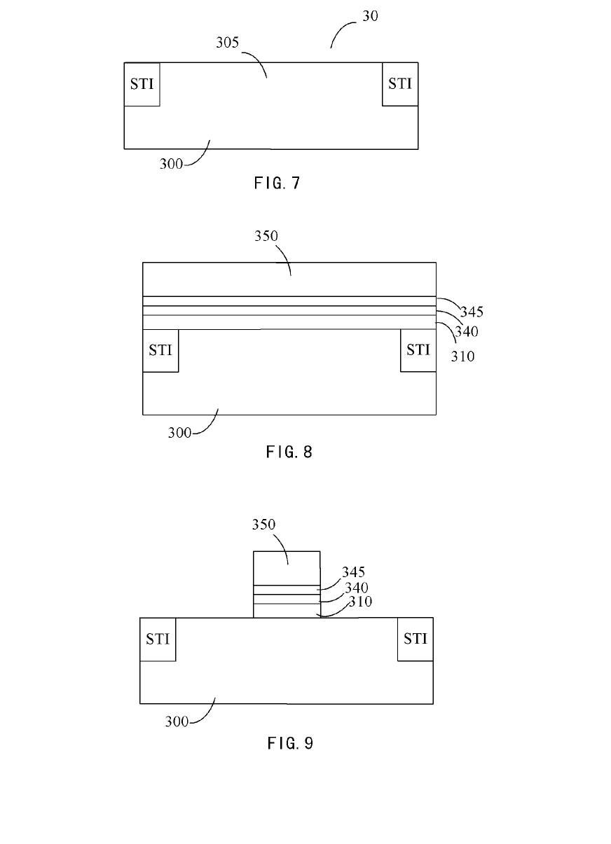

This embodiment is directed to a MOS device manufactured by a gate-first process. An initial structure 30 as shown in FIG. 7 is provided as a start. The initial structure 30 comprises a semiconductor substrate 300, and a channel 305 formed in the semiconductor substrate. The MOS devices may also be separated from each other by an isolation region, which may be, for example, a shallow trench isolation (STI) or field isolation region and may be formed of stressed materials or unstressed materials.

A gate insulating layer 310 is formed on the semiconductor substrate 300, as shown in FIG. 8. The materials for the gate insulating layer may be, for example, various dielectric materials or the composite multi-layer structures thereof. The dielectric materials may include but not limited to HfO₂, HfSiOₓ, HfSiON, HfAlOₓ, HfTaOₓ, HfLaOₓ, HfAlSiOₓ, and HfLaSiOₓ etc., rare-earth based high K dielectric materials such as ZrO₂, La₂O₃, LaAlO₃, TiO₂, Y₂O₃ etc., and SiO₂, SiON, Si₃N₄, Al₂O₃ etc. The gate insulating layer may be formed by a deposition process such as chemical vapor deposition (CVD), plasma assisted CVD, atomic layer deposition (ALD), evaporation, reaction sputtering, chemical solution deposition and other similar deposition processes or the combination of any of the above processes.

A work function regulating layer 340 is deposited on the gate insulating layer 310, as shown in FIG. 8. The work function regulating layer is used for regulating the work function of a metal gate. The materials for the work function regulating layer may be selected from the groups as follows: (1) Mₓ₁N_{y1}, Mₓ₂Si_{y2}N_{z1}, Mₓ₃Al_{y3}N_{z2} or MₐAlₓ₃Si_{y3}N_{z2} deposited by chemical vapor deposition (CVD), plasma assisted CVD (PECVD), atomic layer deposition (ALD), sputtering or other similar deposition processes; (2) a compound of the formula Mₓ₁N_{y1}, Mₓ₂Si_{y2}N_{z1}, Mₓ₃Al_{y3}N_{z2} or MₐAlₓ₃Si_{y3}N_{z2} and metal Co, Ni, Cu, Al, Pd, Pt, Ru, Re, Mo, Ta, Ti, Hf, Zr, W, Ir, Eu, Nd, Er or La sequentially deposited by the above processes, that is, a composite layer comprised of the compound and the metal; or (3) Mₓ₁N_{y1}, Mₓ₂Si_{y2}N_{z1}, Mₓ₃Al_{y3}N_{z2} or MₐAlₓ₃Si_{y3}N_{z2} deposited by the above processes, in which metal Co, Ni, Cu, Al, Pd, Pt, Ru, Re, Mo, Ta, Ti, Hf, Zr, W, Ir, Eu, Nd, Er or La is doped. Wherein letter “M” represents Ta, Ti, Hf, Zr, Mo or W; a, x1-x3, y1-y3 and z1-z2 are the number of atoms of the element in the compound. So long as M is specific, a, x1-x3, y1-y3 and z1-z2 are also determined. Here, it shall be noted that as for an NMOS, an appropriate element M and an appropriate metal element to be doped shall be selected, and the numerical value for a, x1-x3, y1-y3 and z1-z2 as well as the deposition process shall be regulated such that the work function of the material can approach the bottom of the conduction band; as for a PMOS, an appropriate element M and an appropriate metal element to be doped shall be selected, and the numerical value for a, x1-x3, y1-y3 and z1-z2 as well as a deposition process shall be regulated such that the work function of the material can approach the top of the valence band. As for how to select corresponding process parameters and materials for the NMOS or the PMOS such that the work function of the material can approach the bottom of the conduction band or the top of the valence band, it is well known by a person skilled in the art, no more unnecessary details will be provided here.

Next, a strained metal layer 350 is formed on the top of the work function regulating layer 340, as shown in FIG. 8. The strained metal layer introduces a stress to the channel. The materials for the strained metal layer 350 may be selected from the groups as follows: (1) high-stress (the tensile stress>3 Gpa or the compressive stress<−3 Gpa) Mₓ₁N_{y1}, Mₓ₂Si_{y2}N_{z1}, Mₓ₃Al_{y3}N_{z2} or MₐAlₓ₃Si_{y3}N_{z2} deposited by CVD, PECVD, ALD or sputtering; (2) high-stress (the tensile stress>3 Gpa or the compressive stress<−3 Gpa) pure metal Co, Ni, Cu, Al, Pd, Pt, Ru, Re, Mo, Ta, Ti, Hf, Zr, W, Ir, Eu, Nd, Er or La deposited by the above similar processes; (3) high-stress (the tensile stress>3 Gpa or the compressive stress<−3 Gpa) Mₓ₁N_{y1}, Mₓ₂Si_{y2}N_{z1}, Mₓ₃Al_{y3}N_{z2} or MₐAlₓ₃Si_{y3}N_{z2} deposited by the above similar processes, in which metal Co, Ni, Cu, Al, Pd, Pt, Ru, Re, Mo, Ta, Ti, Hf, Zr, W, Ir, Eu, Nd, Er or La is doped; (4) metalization reactants of Si or Ge such as CoSi₂, TiSi₂, NiSi, PtSi, NiPtSi, CoGeSi, TiGeSi or NiGeSi; (5) high-stress (the tensile stress>3 Gpa or the compressive stress<−3 Gpa) metal oxide deposited by the above similar processes such as In₂O₃, SnO₂, ITO, or IZO; (6) high-stress (the tensile stress>3 Gpa or the compressive stress<−3 Gpa) polysilicon, amorphous silicon, polycrystalline germanium, or polycrystalline silicon-germanium deposited by the above similar processes; or (7) any one of the materials in the above (1)-(6) which has experienced high temperature rapid thermal annealing (for example, laser annealing or spike annealing), in which C,F,N,O,B,P or As may also be ion implanted. Wherein letter “M” represents Ta, Ti, Hf, Zr, Mo or W; and a, x1-x3, y1-y3 and z1-z2 are the number of atoms of the element in the compound. So long as M is specific, a, x1-x3, y1-y3 and z1-z2 are also determined. Here, it shall be noted that as for an NMOS, an appropriate metal material and ratio of components, an appropriate deposition process and post-processing method shall be selected such that the intrinsic stress of the material is a compressive stress and is greater than 3 Gpa; as for a PMOS, an appropriate metal material and ratio of components, an appropriate deposition process and post-processing method shall be selected such that the intrinsic stress of the material is a tensile stress and is greater than 3 Gpa. As for how to select corresponding process parameters and materials for the NMOS or the PMOS such that its intrinsic stress is greater than 3 Gpa, it may be achieved by a person skilled in the art through limited experiments, no more unnecessary details will be provided here.

Preferably, a blocking layer 345 may also be formed between the work function regulating layer 340 and the strained metal layer 350, as shown in FIG. 8. The blocking layer may suppress the mutual diffusion of different elements, thereby improving the stability of the work function of the metal material at the surface, and improving the adhesivity of the strained metal layer and the gate structure in the mean time. The materials for the blocking layer may be selected from the group as follows: Mₓ₁N_{y1}, Mₓ₂Si_{y2}N_{z1}, Mₓ₃Al_{y3}N_{z2} or MₐAlₓ₃Si_{y3}N_{z2} deposited by CVD, PECVD, ALD or sputtering. Wherein letter “M” represents Ta, Ti, Hf, Zr, Mo or W; and a, x1-x3, y1-y3 and z1-z2 are the number of atoms of the element in the compound. So long as M is specific, a, x1-x3, y1-y3 and z1-z2 are also determined.

Then, a gate stack layer is formed by, e.g., a selective etching process. Specifically, the etching is performed by means of a patterned mask, the work function regulating layer 340, strained metal layer 350, and blocking layer 345 (if any) that are remained after etching form a multi-layer metal gate structure, and the multi-layer metal structure and the gate insulating layer remained after etching form the gate stack, as shown in FIG. 9. The work function regulating layer 340 in the multi-layer structure optimizes the corresponding work function (that is, more close to the top of the valence band or the bottom of the conduction band) by optimizing the material, component, process and processing method, thereby to regulate the device threshold to be optimal; the strained metal layer 350 optimizes the corresponding intrinsic stress of the material (that is, compressive stress and tensile stress) by optimizing the material, component, process and processing method, thereby to apply a more effective strain effect to the channel of the device; the blocking layer 345 improves the stability and the material compatibility. Such a structure overcomes the defect incurred by the fact that a conventional strained metal gate material 105 can not achieve both regulation of work function and effect of application of strain be optimized at the same time.

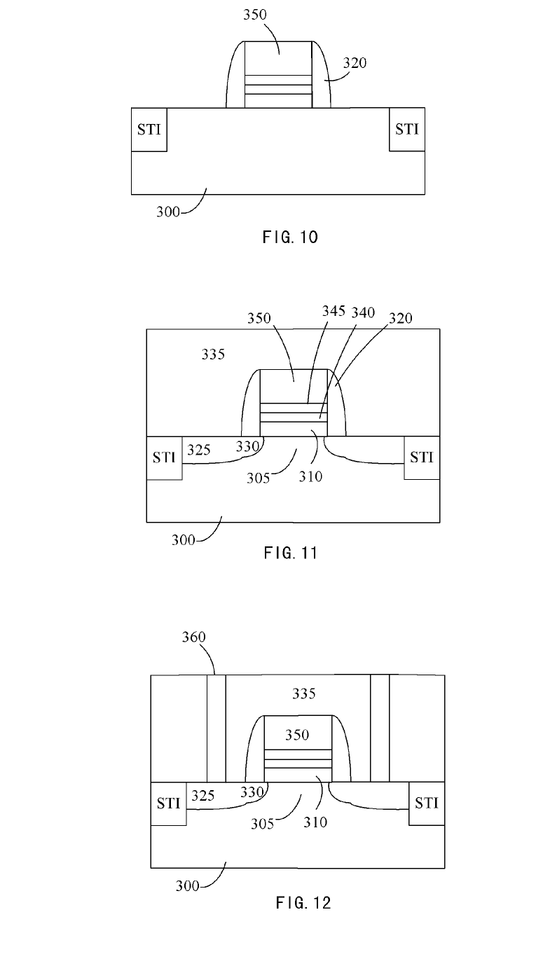

And then, a spacer 320 is formed on both sides of the gate stack, as shown in FIG. 10. The materials for the spacer 320 may include but not limited to nitride.

Optionally, a conventional stressed structure (not shown in the drawings) may be embedded into the source and drain regions on both sides of the gate stack. As for the NMOS device, for example, an SiC (e-SiC) structure or a structure that can provide a tensile stress to the channel formed by any future techniques is embedded into the source and drain regions. As for the PMOS device, for example, an SiGe (e-SiGe) structure or a structure that can provide a compressive stress to the channel formed by any future techniques is embedded into the source and drain regions.

Next, the original spacer 320 is removed to form source and drain regions extension areas 330, then a new spacer is formed and source and drain regions 325 are formed by conventional implanting and annealing processes, and then silicide contacts (not shown) and an interlayer dielectric layer 335 on both sides of the gate stack are formed and planarized for the following interconnection process, as shown FIG. 11.

Optionally, a stress liner (not shown) is formed on the top of the device structure already formed prior to formation of the interlayer dielectric layer 335. Depending on the type of the MOS device, the liner may apply a corresponding stress to the channel region under the gate stack, to thereby improve the carrier mobility in the channel. The stress liner may either be a nitride liner or an oxide liner. However, it may be appreciated by a person skilled in the art that the stress liner is not limited to the nitride liner or the oxide liner, other stress liner materials may also be used. The method for forming the stress liner may include but not limit to the plasma enhanced chemical vapor deposition (PECVD) process.

Next, through other well-known steps, metal contacts 360 are formed in the interlayer dielectric layer 335, to thereby form the MOS device as shown in FIG. 12. In any of the cases, in order not to blur the essence of the present invention, a person skilled in the art may get to know the details of these steps by referring to other publications or patents.

The present invention is applicable to both a PMOS device and an NMOS device, under the teaching of the present invention, it may be appreciated by a person skilled in the art that the method and structure disclosed in the present invention are also applicable to a COMS device.

The scope of the present invention includes any other embodiments and applications that adopt the above structures and methods. Therefore, the scope of the present invention shall be determined by referring to the attached claims as well as the equivalents that have been assigned such claims.

1. A MOS device, comprising:
a semiconductor substrate;
a channel formed in the semiconductor substrate;
a gate stack formed on the channel and a spacer surrounding the gate stack; and
source and drain regions formed in the substrate on both sides of the spacer;
wherein the gate stack is comprised of an insulating layer and a multi-layer metal gate formed thereon, the multi-layer metal gate is comprised of a strained metal layer for introducing a stress to the channel and a work function regulating layer for regulating the work function of the metal gate, and the work function regulating layer surrounds the strained metal layer from the bottom and sides.

2. The MOS device according to claim 1, further comprising a blocking layer formed between the work function regulating layer and the strained metal layer.

3. The MOS device according to claim 1, wherein when the MOS device is a NMOS device, the work function of the material for the work function regulating layer approaches the bottom of the conduction band; when the MOS device is a PMOS device, the work function of the material for the work function regulating layer approaches the top of the valence band.

4. The CMOS device according to claim 3, wherein the materials for the work function regulating layer may be selected from the groups as follows:
(1) a compound of the formula of Mₓ₁N_{y1}, Mₓ₂Si_{y2}N_{z1}, Mₓ₃Al_{y3}N_{z2} or MₐAlₓ₃Si_{y3}N_{z2};
(2) a composite layer of a compound of the formula Mₓ₁N_{y1}, Mₓ₂Si₂N_{z1}, Mₓ₃Al_{y3}N_{z2} or MₐAlₓ₃Si_{y3}N_{z2} and metal Co, Ni, Cu, Al, Pd, Pt, Ru, Re, Mo, Ta, Ti, Hf, Zr, W, Ir, Eu, Nd, Er or La; or
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
wherein the letter “M” represents Ta, Ti, Hf, Zr, Mo or W; and a, x1-x3, y1-y3 and z1-z2 are the number of atoms of the corresponding element in the compound.

5. The MOS device according to claim 1, wherein when the MOS device is an NMOS, an intrinsic stress of the strained metal layer is a compressive stress and is greater than 3 Gpa; and when the MOS device is a PMOS, an intrinsic stress of the strained metal layer is a tensile stress and is greater than 3 Gpa.

6. The MOS device according to claim 5, wherein the materials for the strained metal layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) metal Co, Ni, Cu, Al, Pd, Pt, Ru, Re, Mo, Ta, Ti, Hf, Zr, W, Ir, Eu, Nd, Er or La;
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
(4) CoSi₂, TiSi₂, NiSi, PtSi, NiPtSi, CoGeSi, TiGeSi or NiGeSi;
(5) In₂O₃, SnO₂, ITO, or IZO;
(6) polysilicon, amorphous silicon, polycrystalline germanium, or polycrystalline silicon-germanium; or
(7) any one of the materials in the above (1)-(6) which has experienced high temperature rapid thermal annealing,
wherein the letter “M” represents Ta, Ti, Hf, Zr, Mo or W; and a, x1-x3, y1-y3 and z1-z2 are the number of atoms of the element in the compound.

7. The MOS device according to claim 6, wherein C, F, N, O, B, P or As is further implanted in any one of the materials in (7).

8. The MOS device according to claim 2, wherein the materials for the blocking layer is a compound of the formula Mₓ₁N_{y1}, Mₓ₂Si_{y2}N_{z1}, Mₓ₃Al_{y3}N_{z2} or MₐAlₓ₃Si_{y3}N_{z2}, wherein letter “M” represents Ta, Ti, Hf, Zr, Mo or W, and a, x1-x3, y1-y3 and z1-z2 are the number of atoms of the corresponding element in the compound.

9. A method for manufacturing a MOS device, comprising the steps of:
providing an initial structure including a semiconductor substrate, a channel formed in the semiconductor substrate; a gate stack including a gate insulating layer and a sacrificial gate thereon formed above the channel; a spacer surrounding the gate stack, and source and drain regions formed in the substrate on both sides of the spacer;
removing the sacrificial gate;
forming a work function regulating layer for regulating the work function of a multi-layer metal gate to be formed in an opening which is formed after removing the sacrificial gate; and
forming a strained metal layer for introducing a stress to the channel, the work function regulating layer surrounding the strained metal layer from the bottom and sides, and the strained metal layer and the work function regulating layer forming the multi-layer metal gate.

10. The method according to claim 9, further comprising forming a blocking layer between the work function regulating layer and the strained metal layer.

11. The method according to claim 9, wherein when the MOS device is an NMOS device, the work function of the materials for the work function regulating layer is regulated such that it approaches the bottom of the conduction band; when the MOS device is a PMOS device, the work function of the materials for the work function regulating layer is regulated such that it approaches the top of the valence band.

12. The method according to claim 11, wherein the materials for the work function regulating layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) a composite layer of compound Mₓ₁N_{y1}, Mₓ₂Si_{y2}N_{z1}, Mₓ₃Al_{y3}N_{z2} or MₐAlₓ₃Si_{y3}N_{z2} and metal Co, Ni, Cu, Al, Pd, Pt, Ru, Re, Mo, Ta, Ti, Hf, Zr, W, Ir, Eu, Nd, Er or La; or
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
wherein letter “M” represents Ta, Ti, Hf, Zr, Mo or W; and a, x1-x3, y1-y3 and z1-z2 are the number of atoms of the corresponding element in the compound.

13. The method according to claim 9, wherein when the MOS device is an NMOS, an intrinsic stress of the strained metal layer is designed to be a compressive stress and is greater than 3 Gpa; and when the MOS device is a PMOS, an intrinsic stress of the strained metal layer is designed to be a tensile stress and is greater than 3 Gpa.

14. The method according to claim 13, wherein the materials for the strained metal layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) metal Co, Ni, Cu, Al, Pd, Pt, Ru, Re, Mo, Ta, Ti, Hf, Zr, W, Ir, Eu, Nd, Er or La;
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
(4) CoSi₂, TiSi₂, NiSi, PtSi, NiPtSi, CoGeSi, TiGeSi or NiGeSi;
(5) In₂O₃, SnO₂, ITO, or IZO;
(6) polysilicon, amorphous silicon, polycrystalline germanium, or polycrystalline silicon-germanium; or
(7) any one of the materials in the above (1)-(6) which has experienced high temperature rapid thermal annealing,
wherein letter “M” represents Ta, Ti, Hf, Zr, Mo or W; and a, x1-x3, y1-y3 and z1-z2 are the number of atoms of the element in the compound.

15. The method according to claim 14, wherein C, F, N, O, B, P or As is further implanted in any one of the materials in (7).

16. The method according to claim 10, wherein the materials for the blocking layer is a compound of the formula Mₓ₁N_{y1}, Mₓ₂Si₂N_{z1}, Mₓ₃Al_{y3}N_{z2} or MₐAlₓ₃Si_{y3}N_{z2}, wherein letter “M” represents Ta, Ti, Hf, Zr, Mo or W, and a, x1-x3, y1-y3 and z1-z2 are the number of atoms of the corresponding element in the compound.

17. A MOS device, comprising:
a semiconductor substrate;
a channel formed in the semiconductor substrate;
a gate stack formed on the channel and a spacer surrounding the gate stack; and
source and drain regions formed in the substrates on both sides of the spacer;
wherein the gate stack is comprised of an insulating layer and a multi-layer metal gate formed thereon, the multi-layer metal gate is comprised of a work function regulating layer for regulating the work function of the metal gate and a strained metal layer formed on its top for introducing a stress to the channel.

18. The MOS device according to claim 17, further comprising a blocking layer formed between the work function regulating layer and the strained metal layer.

19. The MOS device according to claim 17, wherein when the MOS device is an NMOS device, the work function of the material for the work function regulating layer approaches the bottom of the conduction band; when the MOS device is a PMOS device, the work function of the material for the work function regulating layer approaches the top of the valence band.

20. The CMOS device according to claim 19, wherein the materials for the work function regulating layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) a composite layer of compound Mₓ₁N_{y1}, Mₓ₂Si_{y2}N_{z1}, Mₓ₃Al_{y3}N_{z2} or MₐAlₓ₃Si_{y3}N_{z2} and metal Co, Ni, Cu, Al, Pd, Pt, Ru, Re, Mo, Ta, Ti, Hf, Zr, W, Ir, Eu, Nd, Er or La; or
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
wherein letter “M” represents Ta, Ti, Hf, Zr, Mo or W; and a, x1-x3, y1-y3 and z1-z2 are the number of atoms of the corresponding element in the compound.

21. The MOS device according to claim 17, wherein when the MOS device is an NMOS, an intrinsic stress of the strained metal layer is a compressive stress and is greater than 3 Gpa; and when the MOS device is a PMOS, an intrinsic stress of the strained metal layer is a tensile stress and is greater than 3 Gpa.

22. The MOS device according to claim 21, wherein the materials for the strained metal layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) metal Co, Ni, Cu, Al, Pd, Pt, Ru, Re, Mo, Ta, Ti, Hf, Zr, W, Ir, Eu, Nd, Er or La;
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
(4) CoSi₂, TiSi₂, NiSi, PtSi, NiPtSi, CoGeSi, TiGeSi or NiGeSi;
(5) In₂O₃, SnO₂, ITO, or IZO;
(6) polysilicon, amorphous silicon, polycrystalline germanium, or polycrystalline silicon-germanium; or
(7) any one of the material in the above (1)-(6) which has experienced high temperature rapid thermal annealing,
wherein letter “M” represents Ta, Ti, Hf, Zr, Mo or W; and a, x1-x3, y1-y3 and z1-z2 are the number of atoms of the element in the compound.

23. The MOS device according to claim 22, wherein C, F, N, O, B, P or As is further implanted in any one of the materials in (7).

24. The MOS device according to claim 18, wherein the materials for the blocking layer is a compound of the formula Mₓ₁N_{y1}, Mₓ₂Si_{y2}N_{z1}, Mₓ₃Al_{y3}N₂ or MₐAlₓ₃Si_{y3}N_{z2}, wherein letter “M” represents Ta, Ti, Hf, Zr, Mo or W, and a, x1-x3, y1-y3 and z1-z2 are the number of atoms of the corresponding element in the compound.

25. A method for manufacturing a MOS device, comprising the steps of:
providing a semiconductor substrate;
forming a channel in the semiconductor substrate;
forming sequentially on the semiconductor substrate a gate insulating layer, a work function regulating layer for regulating the work function and a strained metal layer for introducing a stress to the channel;
patterning a part of the gate insulating layer, work function regulating layer and strained metal layer to form a gate stack layer, wherein the gate stack layer is comprised of the remaining gate insulating layer, work function regulating layer and strained metal layer;
forming a spacer on both sides of the gate stack layer; and
forming source and drain regions in the substrate on both sides of the spacer.

26. The method according to claim 25, further comprising forming a blocking layer between the work function regulating layer and the strained metal layer.

27. The method according to claim 25, wherein when the MOS device is an NMOS device, the work function of the materials for the work function regulating layer is regulated such that it approaches the bottom of the conduction band; when the MOS device is a PMOS device, the work function of the materials for the work function regulating layer is regulated such that it approaches the top of the valence band.

28. The method according to claim 27, wherein the materials for the work function regulating layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) a composite layer of compound Mₓ₁N_{y1}, Mₓ₂Si_{y2}N_{z1}, Mₓ₃Al_{y3}N_{z2} or MₐAlₓ₃Si_{y3}N_{z2} and metal Co, Ni, Cu, Al, Pd, Pt, Ru, Re, Mo, Ta, Ti, Hf, Zr, W, Ir, Eu, Nd, Er or La; or
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
wherein letter “M” represents Ta, Ti, Hf, Zr, Mo or W; and a, x1-x3, y1-y3 and z1-z2 are the number of atoms of the corresponding element in the compound.

29. The method according to claim 25, wherein when the MOS device is an NMOS, an intrinsic stress of the strained metal layer is a compressive stress and is greater than 3 Gpa; and when the MOS device is a PMOS, an intrinsic stress of the strained metal layer is a tensile stress and is greater than 3 Gpa.

30. The method according to claim 29, wherein the materials for the strained metal layer may be selected from the groups as follows:
(1) a compound of the formula Mₓ₁N_{y1}, Mₓ₂Si_{y2}N_{z1}, Mₓ₃Al_{y3}N_{z2} or MₐAlₓ₃Si_{y3}N_{z2};
(2) metal Co, Ni, Cu, Al, Pd, Pt, Ru, Re, Mo, Ta, Ti, Hf, Zr, W, Ir, Eu, Nd, Er or La;
(3) a compound of the formula Mₓ₁N_{y1}, Mₓ₂Si_{y2}N_{z1}, Mₓ₃Al_{y3}N_{z2} or MₐAlₓ₃Si_{y3}N_{z2} doped with metal Co, Ni, Cu, Al, Pd, Pt, Ru, Re, Mo, Ta, Ti, Hf, Zr, W, Ir, Eu, Nd, Er or La;
(4) CoSi₂, TiSi₂, NiSi, PtSi, NiPtSi, CoGeSi, TiGeSi or NiGeSi;
(5) In₂O₃, SnO₂, ITO, or IZO;
(6) polysilicon, amorphous silicon, polycrystalline germanium, or polycrystalline silicon-germanium; or
(7) any one of the materials in the above (1)-(6) which has experienced high temperature rapid thermal annealing,
wherein letter “M” represents Ta, Ti, Hf, Zr, Mo or W; and a, x1-x3, y1-y3 and z1-z2 are the number of atoms of the element in the compound.

31. The method according to claim 30, wherein C, F, N, O, B, P or As is further implanted in any one of in the materials in (7).

32. The method according to claim 26, wherein the materials for the blocking layer is a compound of the formula Mₓ₁N_{y1}, Mₓ₂Si₂N_{z1}, Mₓ₃Al_{y3}N_{z2} or MₐAlₓ₃Si_{y3}N_{z2}, wherein letter “M” represents Ta, Ti, Hf, Zr, Mo or W, and a, x1-x3, y1-y3 and z1-z2 are the number of atoms of the corresponding element in the compound.
